(19) United States
(12) Patent Application Publication
(10) Pub. No.: US 2025/0316603 A1
(43) Pub. Date: Oct. 9, 2025

(54) ELECTRONIC DEVICE

(71) Applicant: PanelSemi Corporation, New Taipei City (TW)

(72) Inventor: Hsien-Te CHEN, New Taipei City (TW)

(21) Appl. No.: 19/172,793

(22) Filed: Apr. 8, 2025

Related U.S. Application Data
(60) Provisional application No. 63/631,109, filed on Apr. 8, 2024.

(51) Int. Cl. H01L 23/538; G02B 6/42; H01L 23/00; H01L 25/16; H10B 80/00; H10D 80/30

(52) U.S. Cl. CPC H01L 23/5385; G02B 6/4257; H01L 25/162; H01L 25/167; H01L 24/16; H01L 2224/16237; H01L 2924/1432; H01L 2924/1436; H10B 80/00; H10D 80/30

(57) ABSTRACT

An electronic device includes a functional substrate, a conductive layer having a plurality of circuitries on the functional substrate, a plurality of redistribution-layered substrates arranged along one surface of the functional substrate, a plurality of functional components arranged on the functional substrate, and a plurality of computing and memory components arranged on one side of the redistribution-layered substrate.

### CROSS REFERENCE TO RELATED APPLICATIONS

This Non-provisional application claims priority to U.S. provisional patent application with Ser. No. 63/631,109 filed on Apr. 8, 2024. This and all other extrinsic materials discussed herein are incorporated by reference in their entirety.

### BACKGROUND

### Technology Field

The disclosure relates to an electronic device.

### Description of Related Art

There are several methods for improving computing performance of a processor in the art. One method is to minimize transistor size to allow multiple transistors arranged in a compact manner to improve computing performance. Another method is to increase clock frequency of the processor since the transistors can perform more operations per unit time when the clock frequency of the processor is higher, thereby improving the computing performance. An additional method is increasing the number of cores in a processor, so more chip cores can work simultaneously. In addition, improving chip architecture used in a processor can enhance the collaboration efficiency of various components within the chip, thereby improving computing performance.

### SUMMARY

One or more exemplary embodiments of this disclosure aim to provide an electronic device that incorporates a heterogeneous architecture to adapt to the semiconductor industry and achieve high computing performance.

An electronic device comprises a functional substrate, a conductive layer, a plurality of redistribution-layered substrates, a plurality of functional components, and a plurality of computing and memory components. The functional substrate defines a first surface and a second surface opposite to each other. The conductive layer is arranged on the functional substrate and includes a plurality of circuitries. The redistribution-layered substrates are arranged along the first surface of the functional substrate. One or ones of the redistribution-layered substrates includes a redistribution layer corresponds and electrically connects to one or ones of the circuitries on the conductive layer. One redistribution-layered substrates is communicated to another one by either one or both of electrical signals and optical signals. The functional components are arranged on the functional substrate and electrically connect the conductive layer. The computing and memory components are arranged on one side the redistribution-layered substrate(s) which is/are opposite to the first surface of the functional substrate. Ones of the computing and memory components electrically connect the redistribution layer of a corresponding one of the redistribution-layered substrates.

This disclosure also provides an electronic device, which comprised a functional substrate, a conductive layer, one redistribution-layered substrate, a plurality of functional components, and a plurality of computing and memory components. The functional substrate defines a first surface and a second surface opposite to each other. The conductive layer is arranged on the functional substrate and defines a plurality of circuitries. The redistribution-layered substrate is arranged along the first surface of the functional substrate, and the redistribution-layered substrate includes a redistribution layer corresponding and electrically connects to one or ones of the circuitries of the conductive layer. The plurality of functional components is arranged on the functional substrate and electrically connects the conductive layer. The plurality of computing and memory components is arranged on one side opposite to the first surface of the substrate of the redistribution-layered substrate. The plurality of the computing and memory components is electrically connected to the redistribution layer of the redistribution-layered substrate. One of the computing and memory components is communicated to another one of the computing and memory components by either one or both of electrical signals and optical signals.

In one embodiment, the redistribution-layered substrate(s) is/are resilient.

In one embodiment, ones of the circuitries are arranged in a matrix, the conductive layer further includes a plurality of conductive traces electrically connecting the circuitries arranged in a matrix.

In one embodiment, the electronic device further includes a plurality of optical traces for traveling the optical signals.

In one embodiment, one of the redistribution-layered substrates is coupled with one another by corresponding one or ones of the optical traces.

In one embodiment, one or ones of the computing and memory components arranged on the corresponding one of the redistribution-layered substrates is/are communicated by the optical signals traveling by corresponding one or ones of the optical trace.

In one embodiment, at least partial of one or ones of the optical traces is arranged below the first surface of the functional substrate.

In one embodiment, the optical traces includes any combination of optical fibers, waveguides, and optical components.

In one embodiment, the waveguides include any combination of dielectric slab waveguide, two-dimensional waveguide, light pipe and optical fiber waveguide.

In one embodiment, the waveguides include silicon waveguide, silicon oxynitride (SiON) waveguide, silicon nitride (Si₃N₄) waveguide, lithium niobate (LiNbO₃) waveguide, aluminum nitride (AlN) waveguide, aluminum gallium arsenide (AlGaAs) waveguide, gallium nitride (GaN) waveguide, and gallium phosphide (GaP) waveguide.

In one embodiment, the material of the waveguides include any combination of silicon, silicon oxynitride (SiON), silicon nitride (Si₃N₄), lithium niobate (LiNbO₃), aluminum nitride (AlN), aluminum gallium arsenide (AlGaAs), gallium nitride (GaN), and gallium phosphide (GaP).

In one embodiment, the optical traces are arranged in a matrix.

In one embodiment, the optical traces are arranged in either or both of longitudinal direction and transverse direction.

In one embodiment, ones of the optical traces are communicated through a switching unit which can switch a traveling direction of the optical signals.

In one embodiment, ones of the optical traces are crossover with one another and coupled with a switching unit arranged at where the optical traces cross.

In one embodiment, the switching unit includes an optical switching element.

In one embodiment, the switching unit includes a signal amplifier.

In one embodiment, ones of the computing and memory components arranged on corresponding ones of the redistribution-layered substrate are identical.

In one embodiment, at least partial of the conductive layer defines a trace space no greater than 50 μm.

In one embodiment, the trace space of at least partial of the conductive layer is no greater than 30 82 m.

In one embodiment, the trace space of at least partial of the conductive layer is no greater than 15 82 m.

In one embodiment, at least partial of the conductive layer defines a thickness no greater than 20 μm.

In one embodiment, the thickness of at least partial of the conductive layer is no greater than 10 μm.

In one embodiment, one or both of electrical signals and optical signals of one of the redistribution-layered substrates optionally travel(s) to another one or ones of the redistribution-layered substrates.

In one embodiment, the computing and memory components includes a plurality of I/O (input/output) ports, and a quantity of the I/O ports of one or ones of the computing and memory components is no less than 300.

### BRIEF DESCRIPTION OF THE DRAWINGS

The disclosure will become more fully understood from the detailed description and accompanying drawings, which are given for illustration only, and thus are not limitative of the present disclosure, and wherein:

FIG. 1 is a cross-section profile showing an electronic device according to an embodiment of this disclosure;

FIG. 2 is a cross-section profile showing an electronic device according to a second embodiment of this disclosure;

FIG. 3A to FIG. 3C are cross-section profiles showing arrangement of the computing and memory components of this disclosure;

FIG. 4A to FIG. 4C are cross-section profiles showing arrangement of optical fibers of this disclosure; and

FIG. 5A to FIG. 5C are top views showing arrangement of multiple redistribution-layered substrates on a functional substrate of this disclosure.

### DETAILED DESCRIPTION OF THE DISCLOSURE

The disclosure will become fully understood from the detailed description and accompanying drawings, which are given for illustration only, and thus are not limitative of the present disclosure. In the accompanying drawings, same reference numerals refer to the same or analogous elements shown so that, unless stated otherwise, explanations of an element with a given reference numeral provided in context of one of the drawings are applicable to other drawings where element with the same reference numerals may be illustrated.

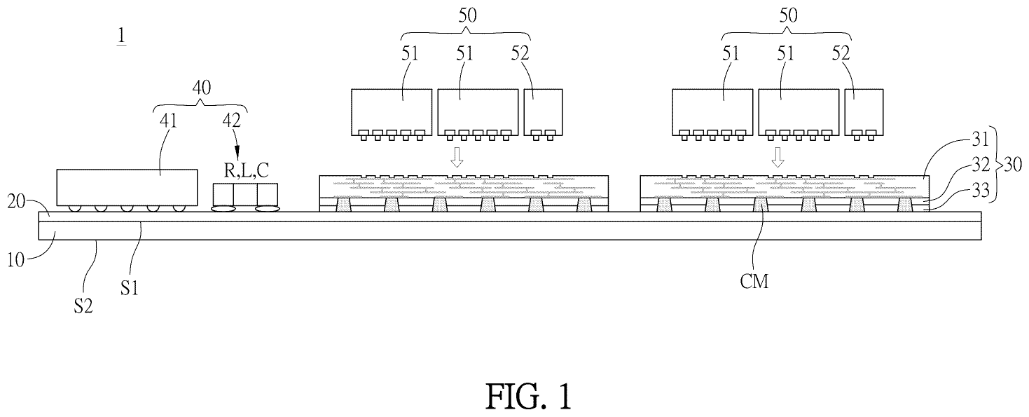

This disclosure relates to an electronic device, as shown in FIG. 1, the electronic device 1 includes a functional substrate 10, a conductive layer 20, a plurality of redistribution-layered substrates 30, a plurality of functional components 40, and a plurality of computing and memory components 50. The functional substrate 10 defines a first surface S1 and a second surface S2 opposite to each other. The conductive layer 20 is arranged on first surface S1 of the functional substrate 10 and includes a plurality of circuitries (not illustrated). The redistribution-layered substrates 30 are arranged along the first surface S1 of the functional substrate 10 and electrically connect ones of the circuitries of the conductive layer 20. The ratio of the amount the circuitries on the conductive layer 20 to the amount of the redistribution-layered substrates arranged on or in the functional board 10 is not limited. One or ones of the redistribution-layered substrates 30 includes a redistribution layer 31 and a plurality of conductive members CM, and the conductive members CM electrically connect the redistribution layer 31 with corresponding ones of the circuitries of the conductive layer 20. One of the circuitries can be communicated to another one by either one or both of electrical signals and optical signals. The functional components 40 are arranged on the functional substrate 10 and electrically connect the conductive layer 20. The computing and memory components 50 are arranged on one side of the redistribution-layered substrates 30, which is opposite to the first surface S1 of the functional substrate 10. The computing and memory components 50 electrically connect one corresponding redistribution layer 31 of one of the redistribution-layered substrates 30.

In one case, the functional substrate 10 can be a BT (Bismaleimide Triazine) substrate, a PPO (polyphenol oxidase) substrate, a Rogers substrate, a glass substrate, a ceramic substrate, or substrates having similar functions, but not limited to.

In one case, the circuitries on the conductive layer 20 are arranged in a matrix, and the conductive layer 20 further includes a plurality of conductive traces electrically connecting the circuitries for transmission of the electrical signals. In one case, at least partial of the traces of the conductive layer 20 defines a trace space no greater than 50 μm, or no greater than 30 μm, or no greater than 15 μm, but not limited thereto. In addition, at least partial of the conductive traces of the conductive layer 20 defines a thickness no greater than 20 μm or 10 μm, but not limited thereto. In one case, ones of the conductive traces are crossover with one another and coupled with a switching unit (not illustrated), and the switching unit is arranged at where the traces cross. Here we know the switching unit works for electrical signals transmission.

In one case, the redistribution-layered substrate 30 can be a multi-layered substrate or a complex substrate, which includes a resilient layer 32 between the redistribution layer 31 and the conductive layer 20. Furthermore, a bonding layer 33 can be arranged between the redistribution layer 31 and the conductive layer 20 (In FIG. 1, the bonding layer 33 is between the resilient layer 32 and the conductive layer 20). In some cases, the redistribution layer 31 and/or the resilient layer 32 is made with resilient materials, for example, polyimide (PI), but not limited thereto. To be noted, the order of manufacturing and materials of the resilient layer 32 and the bonding layer 33 is not limited. The plurality of the circuitries can be arranged in a matrix, and the conductive layer 20 further includes a plurality of conductive traces electrically connecting the matrixed circuitries. The conductive members CM can be vias passing through the resilient layer 32 and filling with conductive materials therein. In addition, the conductive member CM can further pass through the bonding layer 33. As shown in FIG. 1, the conductive members CM pass through the resilient layer 32 and the bonding layer 33. The conductive members CM electrically connect the conductive layer 20 and the redistribution layer 31. In some cases, the conductive materials filled in the via of the conductive member CM can be conductive paste, conductive pillar, conductive wire, or any combination thereof, but not limited thereto.

The functional components 40 can include at least one packaged integrated circuit (IC) 41 and at least one passive component 42 (ex. resistor R, capacitor C, and inducer L), but not limited thereto. The functional components 40 distribute the electrical signals to the circuitries.

The computing and memory components 50 can include at least one system-on-chip (SoC) processor 51 and at least one memory unit 52, such as high bandwidth memory (HBM), but not limited thereto. The computing and memory component 50, for example, the system-on-chip processor 51 and the memory unit 52, includes a plurality of input/output (I/O) ports, and the number of the I/O ports of one computing and memory component 50 is no less than 300. In some cases, the plurality of SOCs 51 on a same redistribution-layered substrate 30 can be different types, and the memory units 52 on a same redistribution-layered substrate 30 can also be different types.

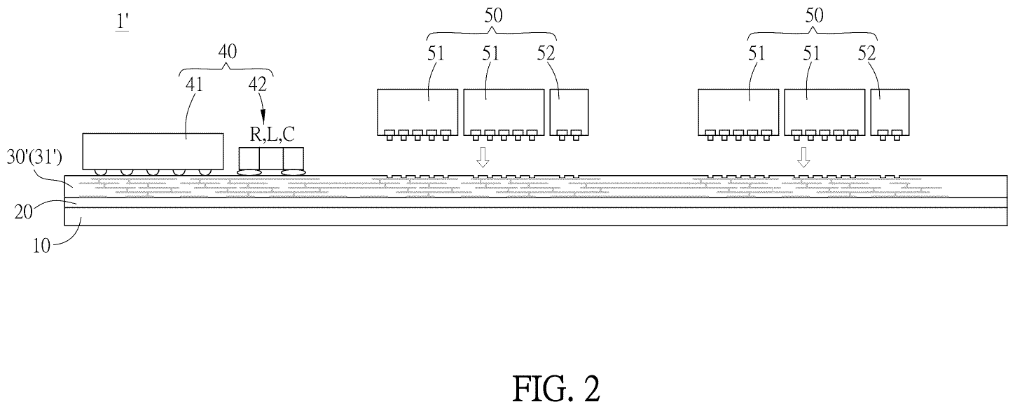

Referring to FIG. 2, ones of the computing and memory components 50 are grouped on a single one redistribution-layered substrate 30′ in the electronic device 1. To be noted, the configuration of ones of the computing and memory components 50 in each group unit may not be identical with one another. In addition, only one redistribution-layered substrate 30′ is arranged on and stretched along the functional substrate 10 in FIG. 2, and the redistribution-layered substrate 30′ electrically connects the conductive layer 20. In this case, the redistribution-layered substrate 30′ can just be a redistribution layer 31′. The functional substrate 10 in this case can be a glass substrate, and the redistribution layer 31′ is formed on the glass substrate.

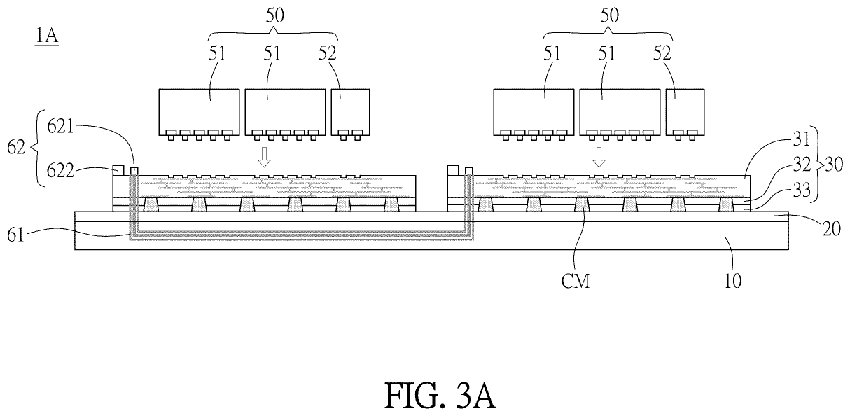

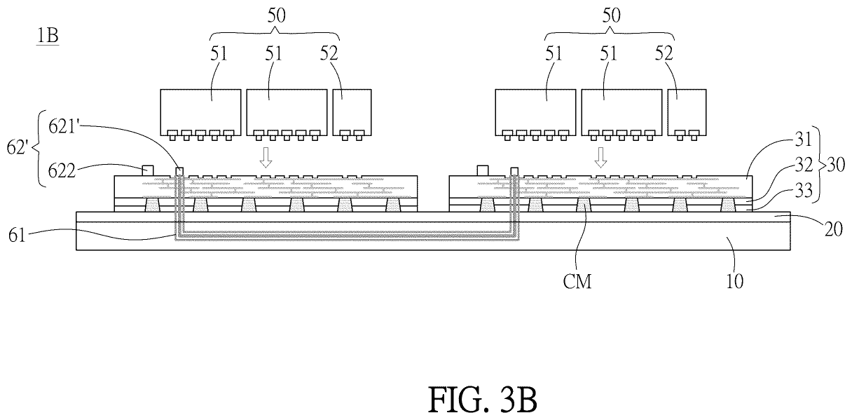

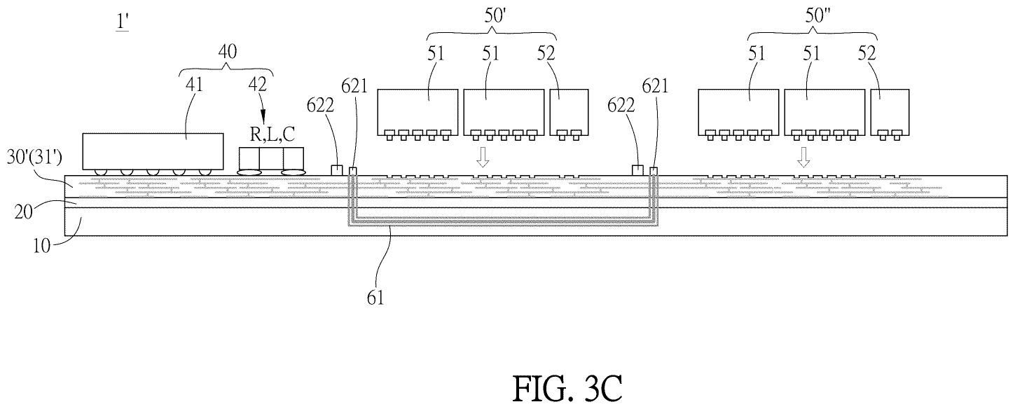

Referred in FIGS. 3A and 3B, the electronic device 1A further includes a plurality of optical traces 61 for traveling of the optical signals. The optical traces 61 can be directly provided to the functional substrate 10 or the redistribution-layered substrates 30. In FIG. 3A, the optical traces 61 are directly provided to the functional substrate 10 and communicate at least two of the redistribution-layered substrates 30, and the optical traces 61 corresponds to the redistribution-layered substrates 30. In addition, the electronic device 1A further include photoelectric units 62, and the photoelectric unit 62 comprises one or more photo sensors 621 and one or more photoelectric conversion components 622. The photoelectric units 62 can be arranged on/in the redistribution-layered substrates 30. The optical traces 61 can directly or indirectly couple to the plurality of photoelectric units 62. The computing and memory component 50 communicates to one of the photoelectric units 62. In some cases, the redistribution-layered substrates 30 communicates with one another by one or ones of the optical traces 61, in which the optical trace 61 can be an optical fiber. One or ones of the computing and memory components 50 arranged on one redistribution-layered substrate 30 is communicated with the computing and memory component(s) 50 on another redistribution-layered substrate 30 by the optical signals traveling by the optical trace 61. The optical trace 61 in this case may include any combination of optical fibers, waveguides, and optical components. The optical components may include reflection mirrors, but not limited thereto. The photo sensor 621 may be an LED, whose function is performed by a reverse biased LED. One or ones of the photoelectric units 62, especially the photo sensor 621 illustrated in FIG. 3A, can be arranged on the surface of the redistribution-layered substrates 30, within the redistribution-layered substrates 30, or between the redistribution-layered substrates 30 and the functional substrate 10. In another case as shown in FIG. 3B, one or ones of the photoelectric units 62, especially the photo sensor 621′ of the electronic device 1B, can be arranged on the surface of the redistribution-layered substrates 30 and located between the bonding pads of one of the computing and memory components 50 after the computing and memory component 50 is arranged on the redistribution-layered substrate 30. One of the photoelectric conversion components 622 corresponds to one or ones of the photo sensors 621.

In FIG. 3C, the redistribution-layered substrate 30′ is just the redistribution layer 31′ as in FIG. 2. In this case, only one redistribution-layered substrate 30′ (or redistribution layer 31′) is arranged on the functional substrate 10. In addition, the plurality of functional components 40 are arranged on the redistribution layer 31′. In other words, the plurality of functional components 40 are indirectly arranged on the functional substrate 10. In this case, one of the plurality computing and memory components (e.g. the computing and memory component 50′) can communicate to another one of the plurality computing and memory components (e.g. the computing and memory component 50″) by optical signal traveling in the optical traces 61. However, two of the computing and memory components (e.g. the computing and memory components 50′ and 50″) can also communicate to each other by electronic signal(s). The electronic device 1′ of FIG. 3C is also provided with the photo sensor 621 and the photoelectric conversion components 622.

However, the optical traces 61, such as the optical fibers may bridge two of the redistribution-layered substrates 30 without traveling through the functional substrate 10.

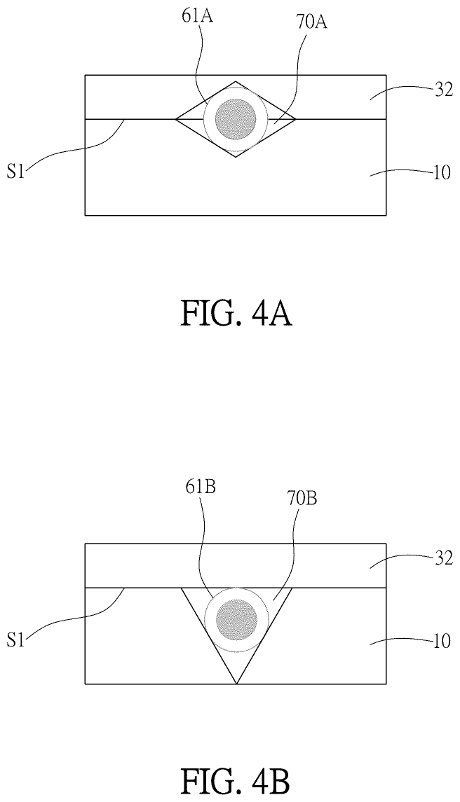

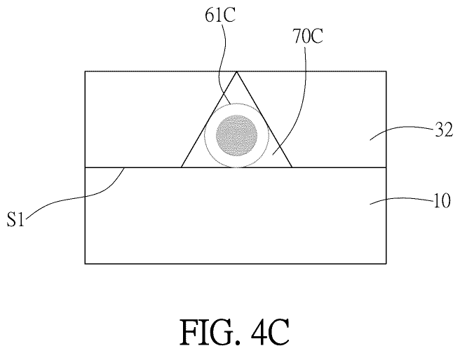

The optical traces, as well as the optical fibers, can be arranged in an accommodating cavity of the electronic device, and the accommodating cavity can be formed in either or both of the functional substrate 10 and the redistribution-layered substrates 30. In the following examples, the accommodating cavity is formed in either or both of the functional substrate 10 and the resilient layer 32 of the redistribution-layered substrates 30, but is not limited thereto. In FIG. 4A, the accommodating cavity 70A is formed by two corresponding concaved region respectively on the functional substrate 10 and the resilient layer 32 of the redistribution-layered substrates 30, and the optical fiber 61A is arranged in the accommodating cavity 70A. In FIG. 4B, the optical fiber 61B is arranged in one accommodating cavity 70B, which is formed by a concaved region on one side of the functional substrate 10 and the resilient layer 32 covered the concaved region. In FIG. 4C, the optical fiber 61C is arranged in one accommodating cavity 70C, which is formed by one concaved region on one side of the resilient layer 32 and the functional substrate 10 covered the concaved region. However, at least partial of the abovementioned optical traces are disposed below the first surface S1 of the functional substrate 10.

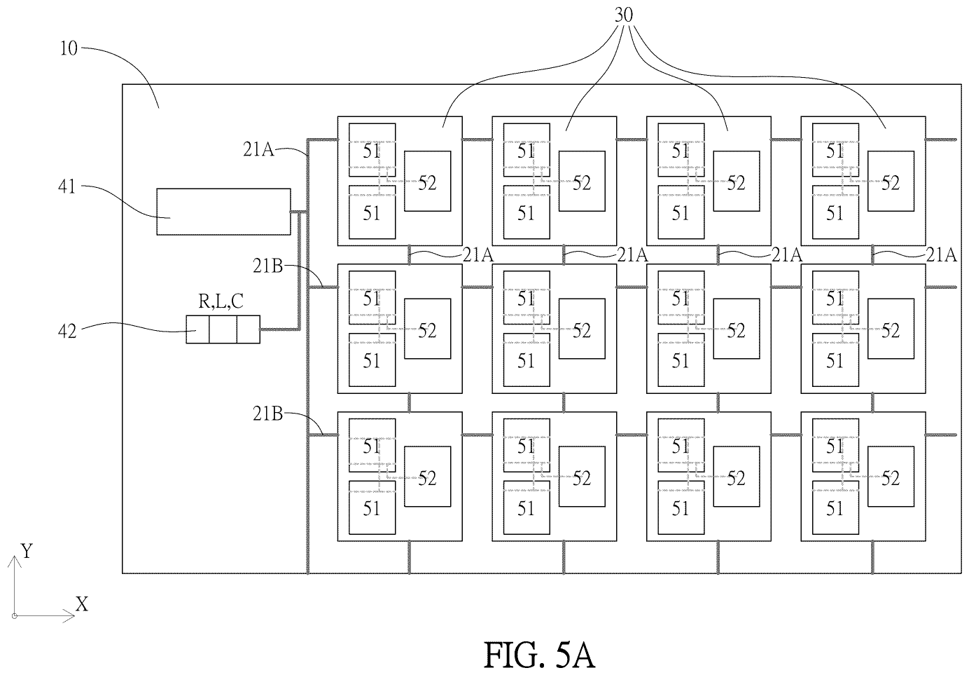

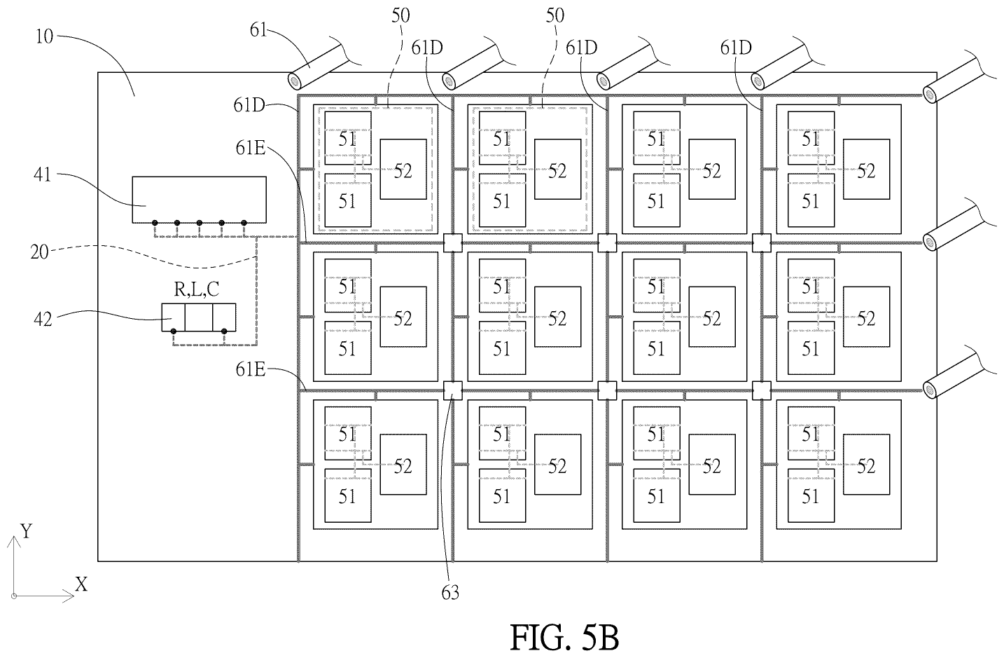

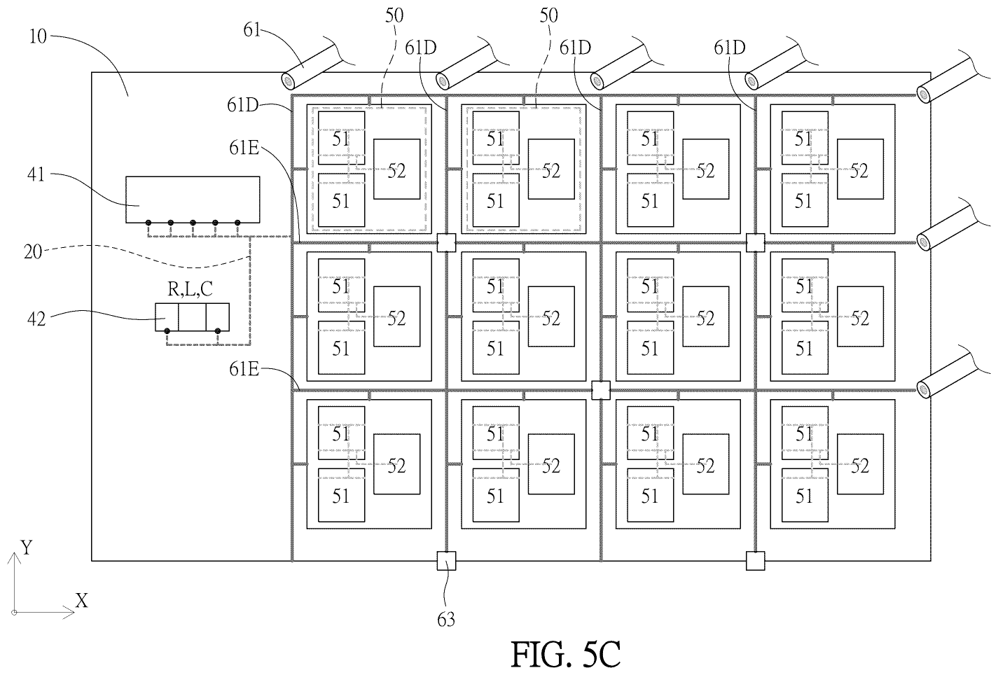

Referring to FIG. 5A, a plurality of redistribution-layered substrates 30 are arranged on a functional substrate 10, and these redistribution-layered substrates 30 are communicated by electrical signals. Therefore, the traces for the electrical signals are conductive traces 21A, 21B. In this case, the redistribution-layer substrates 30 are arranged in a matrix, and these redistribution-layer substrates 30 are communicated with one another by the conductive traces 21A arranged along the Y direction and the conductive traces 21B arranged along the X direction.

In addition, the signals traveling in the electronic device may further include optical signals. Referring to FIG. 5B, the optical traces 61 (61A, 61B) are provided and can be incorporated with the conductive traces. The redistribution-layered substrates 30 couple with one another by one or ones of the optical traces 61, and one or ones of the computing and memory components 50 arranged on one redistribution-layered substrate 30 is communicated to other computing and memory component(s) 50 arranged on another one or ones of the redistribution-layered substrates 30 by the optical signals traveling within the optical trace 61. The optical trace 61 includes either or both of optical fibers and optical structures of a waveguide. In FIG. 5B, the redistribution-layered substrates 30 and the optical traces 61 are arranged in a matrix. In this case, the optical traces 61-D arranged in the Y direction and the optical traces 61E are considered as main optical traces 61 for controlling several redistribution-layered substrates 30, in which the main optical traces 61 can be made with optical fibers. The optical traces 61 arranged in the matrix other than the main optical traces are considered as sub optical traces 61, and the sub optical traces 61 communicate with the redistribution-layered substrates 30 to the corresponding one of the optical traces 61D or the optical traces 61E. The electronic device further includes one or ones of switching units 63 as shown in FIG. 5B and FIG. 5C, and the switching units 63 change a traveling direction of the optical signals. The switching unit 63 is arrange at where the optical traces 61 cross and jointed with. In FIG. 5B, the switching units 63 are arranged at each optical traces 61 intersection, while in FIG. 5C, only several optical traces 61 intersections are provided with the switching units 63. The switching unit 63 in this case may be an optical switching element, and can further include a signal amplifier. In some cases, the ratio of the amount of the optical traces intersection to the amount of the switching units 63 may be not less than 4, but not limited thereto. In addition, the switching unit 63 may include a bundle of optical fibers or a group of waveguide for directing a plurality of the optical signals to corresponding ones of the redistribution-layered substrates 30 or the computing and memory components 50.

In one case, one or both of electrical signals and optical signals of one of the redistribution-layered substrates 30 optionally travel(s) to another one or ones of the redistribution-layered substrates 30. In other words, when one of the redistribution-layered substrates 30, or one or ones of the computing and memory components 50 arranged thereon, is malfunctioning, the signals may be further delivered to another well-functioning one or ones of the redistribution-layered substrates 30 in a way of bypassing the malfunctioning one.

In summary, the electronic device of the present disclosure can flexibly incorporate heterogeneous architecture, and further apply with optical configuration, for adapting to the semiconductor industry with high computing performance. The computing and memory components may contain System-on-Chip (SoC) processors and High Bandwidth Memory (HBM) alongside as close as possible for efficient data processing. Additionally, it utilizes combination of the electrical and the optical signals for high-speed communication between any two redistribution-layered substrates, where different groups of computing and memory components are arranged.

Although the disclosure has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the disclosure.

What is claimed is:

1. An electronic device comprising:
a functional substrate defining a first surface and a second surface opposite to each other;
a conductive layer arranged on the functional substrate and defining a plurality of circuitries;
a plurality of redistribution-layered substrates arranged along the first surface of the functional substrate; wherein one or ones of the redistribution-layered substrates includes a redistribution layer corresponding and electrically connecting to one or ones of the circuitries of the conductive layer; wherein one of the redistribution-layered substrates is communicated to another one of the redistribution-layered substrates by either one or both of electrical signals and optical signals;
a plurality of functional components arranged on the functional substrate and electrically connecting the conductive layer; and
a plurality of computing and memory components arranged on one side of the redistribution-layered substrate(s), which is/are opposite to the first surface of the substrate; wherein ones of the computing and memory components electrically connect the redistribution layer of a corresponding one of the redistribution-layered substrates.

2. The electronic device as claimed in claim 1, wherein the redistribution-layered substrate(s) is/are resilient.

3. The electronic device as claimed in claim 1, wherein ones of the circuitries are arranged in a matrix, and the conductive layer further includes a plurality of conductive traces electrically connecting the circuitries arranged in a matrix.

4. The electronic device as claimed in claim 1, further including a plurality of optical traces for traveling the optical signals.

5. The electronic device as claimed in claim 4, wherein ones of the redistribution-layered substrates are coupled with one another by corresponding one or ones of the optical traces.

6. The electronic device as claimed in claim 4, wherein one or ones of the computing and memory components arranged on the corresponding one of the redistribution-layered substrates is/are communicated by the optical signals traveling by corresponding one or ones of the optical traces.

7. The electronic device as claimed in claim 4, wherein at least partial of one or ones of the optical traces is arranged below the first surface of the functional substrate.

8. The electronic device as claimed in claim 4, wherein the optical traces includes any combination of optical fibers, waveguides, and optical components.

9. The electronic device as claimed in claim 4, wherein the optical traces are arranged in a matrix.

10. The electronic device as claimed in claim 4, wherein the optical traces are arranged in either or both of longitudinal direction and transverse direction.

11. The electronic device as claimed in claim 4, wherein ones of the optical traces are communicated through a switching unit which changes a traveling direction of the optical signals.

12. The electronic device as claimed in claim 11, wherein the switching unit includes an optical switching element.

13. The electronic device as claimed in claim 12, wherein the switching unit includes a signal amplifier.

14. The electronic device as claimed in claim 4, wherein ones of the optical traces are crossover with one another and coupled with a switching unit arranged at where the optical traces cross.

15. The electronic device as claimed in claim 14, wherein the switching unit includes an optical switching element.

16. The electronic device as claimed in claim 15, wherein the switching unit includes a signal amplifier.

17. The electronic device as claimed in claim 1, wherein ones of the computing and memory components arranged on corresponding ones of the redistribution-layered substrate are identical.

18. The electronic device as claimed in claim 1, wherein at least partial of the conductive layer defines a trace space no greater than 50 μm.

19. The electronic device as claimed in claim 1, wherein at least partial of the conductive layer defines a thickness no greater than 20 μm.

20. The electronic device as claimed in claim 1, wherein one or both of electrical signals and optical signals of one of the redistribution-layered substrates optionally travel(s) to another one or ones of the redistribution-layered substrates.

21. The electronic device as claimed in claim 1, wherein the computing and memory components includes a plurality of I/O (input/output) ports, and a quantity of the I/O ports of one or ones of the computing and memory components is no less than 300.

22. An electronic device comprising:
a functional substrate defining a first surface and a second surface opposite to each other;
a conductive layer arranged on the functional substrate and defining a plurality of circuitries;
one redistribution-layered substrate arranged along the first surface of the functional substrate; wherein the redistribution-layered substrate includes a redistribution layer corresponding and electrically connecting to one or ones of the circuitries of the conductive layer;
a plurality of functional components arranged on the functional substrate and electrically connecting the conductive layer; and
a plurality of computing and memory components arranged on one side of the redistribution-layered substrate(s), which is/are opposite to the first surface of the substrate; wherein ones of the computing and memory components electrically connect the redistribution layer of the redistribution-layered substrates, and wherein one of the computing and memory components is communicated to another one of the computing and memory components by either one or both of electrical signals and optical signals.
